(19) United States
(12) Patent Application Publication
(10) Pub. No.: US 2026/0082933 A1
(43) Pub. Date: Mar. 19, 2026

(54) METHOD OF MANUFACTURING SEMICONDUCTOR DEVICE AND SEMICONDUCTOR DEVICE

(71) Applicant: Kioxia Corporation, Tokyo (JP)

(72) Inventors: Koya HOJO, Yokkaichi Mie (JP); Shinichi HIRASAWA, Mie Mie (JP); Hidekazu HAYASHI, Yokkaichi Mie (JP); Yumiko KATAOKA, Yokkaichi Mie (JP)

(21) Appl. No.: 19/065,338

(22) Filed: Feb. 27, 2025

(30) Foreign Application Priority Data
Sep. 13, 2024 (JP) 2024-159573

(51) Int. Cl. H01L 23/544; H01L 21/3105

(52) U.S. Cl. CPC H10W 46/00; H10P 95/062; H10W 46/301

(57) ABSTRACT

A method for manufacturing a semiconductor device includes forming an insulating film on a substrate; forming a recess portion extending toward the substrate from an upper surface of the insulating film; forming a first film on the upper surface of the insulating film and along an inner surface of the recess portion, wherein the first film has hydrophobicity; treating an upper surface of the first film to be hydrophilic; and polishing the first film until the upper surface of the insulating film is exposed.

### CROSS-REFERENCE TO RELATED APPLICATION

This application is based upon and claims the benefit of priority from Japanese Patent Application No. 2024-159573, filed Sep. 13, 2024, the entire contents of which are incorporated herein by reference.

### FIELD

Embodiments described herein relate generally to a method of manufacturing a semiconductor device and a semiconductor device.

### BACKGROUND

When an exposure step in manufacturing steps of a semiconductor device is executed multiple times, a position of an alignment mark may be detected to execute the next exposure step with respect to the position of the alignment mark. For an overlapping accuracy between the previous exposure step and the next exposure step, it is desired to form an alignment mark having excellent visibility.

### DESCRIPTION OF THE DRAWINGS

FIG. 1 is a perspective view illustrating a configuration of a semiconductor device according to a first embodiment.

FIG. 2 is a block diagram illustrating a configuration of the semiconductor device according to the first embodiment.

FIG. 3 is a circuit diagram illustrating a configuration of a memory cell array according to the first embodiment.

FIG. 4 is a cross-sectional view illustrating the configuration of the memory cell array according to the first embodiment.

FIG. 5 is an enlarged cross-sectional view illustrating the configuration of the memory cell array according to the first embodiment.

FIG. 6A is a cross-sectional view illustrating a method of manufacturing the semiconductor device according to the first embodiment.

FIG. 6B is a cross-sectional view continued from FIG. 6A and illustrating the method of manufacturing the semiconductor device.

FIG. 6C is a cross-sectional view continued from FIG. 6B and illustrating the method of manufacturing the semiconductor device.

FIG. 6D is a cross-sectional view continued from FIG. 6C and illustrating the method of manufacturing the semiconductor device.

FIG. 6E is a cross-sectional view continued from FIG. 6D and illustrating the method of manufacturing the semiconductor device.

FIG. 6F is a cross-sectional view continued from FIG. 6E and illustrating the method of manufacturing the semiconductor device.

FIG. 6G is a cross-sectional view continued from FIG. 6F and illustrating the method of manufacturing the semiconductor device.

FIG. 6H is a cross-sectional view continued from FIG. 6G and illustrating the method of manufacturing the semiconductor device.

FIG. 6I is a cross-sectional view continued from FIG. 6H and illustrating the method of manufacturing the semiconductor device.

FIG. 7 is a cross-sectional view illustrating a configuration of a mark according to the first embodiment.

FIG. 8A is a cross-sectional view illustrating the method of manufacturing the semiconductor device according to the first embodiment.

FIG. 8B is a cross-sectional view continued from FIG. 8A and illustrating the method of manufacturing the semiconductor device.

FIG. 8C is a cross-sectional view continued from FIG. 8B and illustrating the method of manufacturing the semiconductor device.

FIG. 8D is a cross-sectional view continued from FIG. 8C and illustrating the method of manufacturing the semiconductor device.

FIG. 8E is a cross-sectional view continued from FIG. 8D and illustrating the method of manufacturing the semiconductor device.

FIG. 9 is a cross-sectional view illustrating a method of manufacturing the semiconductor device according to Comparative Example.

FIG. 10 is a cross-sectional view illustrating a configuration of a mark according to a second embodiment.

FIG. 11A is a cross-sectional view illustrating the method of manufacturing the semiconductor device according to the second embodiment.

FIG. 11B is a cross-sectional view continued from FIG. 11A and illustrating the method of manufacturing the semiconductor device.

FIG. 11C is a cross-sectional view continued from FIG. 11B and illustrating the method of manufacturing the semiconductor device.

### DETAILED DESCRIPTION

Embodiments provide a method of manufacturing a semiconductor device and a semiconductor device capable of more appropriately forming a mark.

In general, according to one embodiment, a method for manufacturing a semiconductor device includes forming an insulating film on a substrate; forming a recess portion extending toward the substrate from an upper surface of the insulating film; forming a first film on the upper surface of the insulating film and along an inner surface of the recess portion, wherein the first film has hydrophobicity; treating an upper surface of the first film to be hydrophilic; and polishing the first film until the upper surface of the insulating film is exposed.

Hereinafter, an embodiment of the present disclosure will be described with reference to the drawings. The present embodiment does not limit the present disclosure. The drawings are schematic or conceptual, in which a ratio between components, and the like are not necessarily the same as the actual ones. In this specification and the drawings, the same components as described above with reference to the previous drawings are represented by the same reference numerals, and the detailed description thereof will not be repeated.

### First Embodiment

A semiconductor device according to a first embodiment has a three-dimensional structure in which a columnar semiconductor film penetrates a stacked body where a plurality of conductive layers are stacked through an insulating layer and a portion adjacent to each of the conductive layers and the semiconductor film functions as a memory cell. In this semiconductor device, a method for improving operation reliability is conceived.

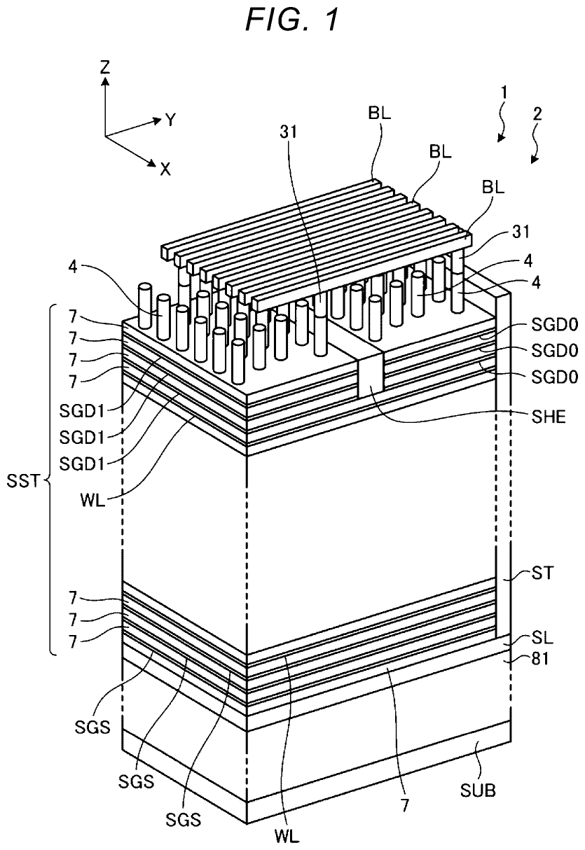

A semiconductor device 1 is configured as illustrated in FIG. 1. FIG. 1 is a perspective view illustrating the schematic configuration of the semiconductor device 1.

In the following description, directions perpendicular to each other in a plane parallel to a surface of a substrate SUB will be referred to as an X direction and a Y direction. More specifically, the X direction is a direction in which a word line WL extends, and the Y direction is a direction in which a bit line BL extends. A Z direction is a direction perpendicular to the surface of the substrate SUB. Therefore, the Z direction is perpendicular to the X direction and the Y direction.

As illustrated in FIG. 1, the semiconductor device 1 includes a select gate SGS, the word line WL, and a select gate SGD. The select gate SGS is stacked on the substrate SUB through an insulating layer 7. In the example of FIG. 1, three select gates SGS are provided. The word line WL is stacked on the uppermost select gate SGS through the insulating layer 7. In the example of FIG. 1, a plurality of word line WL and a plurality of insulating layer 7 are alternately provided in the Z direction. The select gate SGD is stacked on the uppermost word line WL through the insulating layer 7. Each of the select gate SGS, the word line WL, and the select gate SGD has a plate shape extending in the X direction and the Y direction.

In the example of FIG. 1, the select gate SGD, the word line WL, and the select gate SGS are separated and insulated in the Y direction by a slit ST. A source line SL is disposed on the +Z side of the substrate SUB through an interlayer insulating film 81. The slit ST is provided on the +Z side of the source line SL and extends in the X direction and the Z direction.

The select gate SGD is separated in the Y direction, for example, by a separation film SHE. In the example of FIG. 1, select gates SGD0 and SGD1 that are divided in the Y direction are illustrated. The separation film SHE is provided above the word line WL (+Z side) and extends in the X direction and the Z direction. Therefore, the select gate SGD0 and the select gate SGD1 are arranged in the Y direction on the word line WL. In the example of FIG. 1, three select gates SGD0 and three select gates SGD1 are provided.

The substrate SUB is, for example, a silicon substrate. The select gate SGS, the word line WL, and the select gate SGD are, for example, metal layers including tungsten (W). The insulating layer 7 and the interlayer insulating film 81 are, for example, insulators including silicon oxide.

The semiconductor device 1 further includes a plurality of columnar bodies 4. The columnar body 4 penetrates the select gate SGS, the word line WL, and the select gate SGD and extends in the Z direction that is a direction in which the select gate SGS, the word line WL, and the select gate SGD are stacked. The semiconductor device 1 further includes a plurality of bit lines BL provided above the select gate SGD.

Each of the columnar bodies 4 is electrically connected to the bit line BL through a contact plug 31. For example, one of the columnar bodies 4 that share the select gate SGD0 and one of the columnar bodies 4 that share the select gate SGD1 are electrically connected to one bit line BL.

In FIG. 1, in order to simplify the drawing, the interlayer insulating film provided between the select gate SGD and the bit line BL is not illustrated.

In the semiconductor device 1, each of the select gate SGD, the word line WL, and the select gate SGS is configured with a conductive layer. On the +Z side of the source line SL, a stacked body SST where the conductive layer and the insulating layer 7 are alternately stacked is configured. The stacked body SST is penetrated by the columnar body 4 such that the three-dimensional arrangement (memory cell array) of the memory cells is configured.

That is, in the semiconductor device 1, a portion where the word line WL and the columnar body 4 intersect with each other is configured to function as a memory cell, and a memory cell array 2 where a plurality of memory cells are three-dimensionally arranged is configured. In addition, a portion where the select gate SGS and the columnar body 4 intersect with each other functions as a source-side select gate, and portions where the select gates SGD0 and SGD1 and the columnar body 4 intersect with each other function as drain-side select gates. In the semiconductor device 1, by increasing the number of word lines WL stacked in the stacked body SST, the storage capacity can be increased even without using a more refined patterning technique.

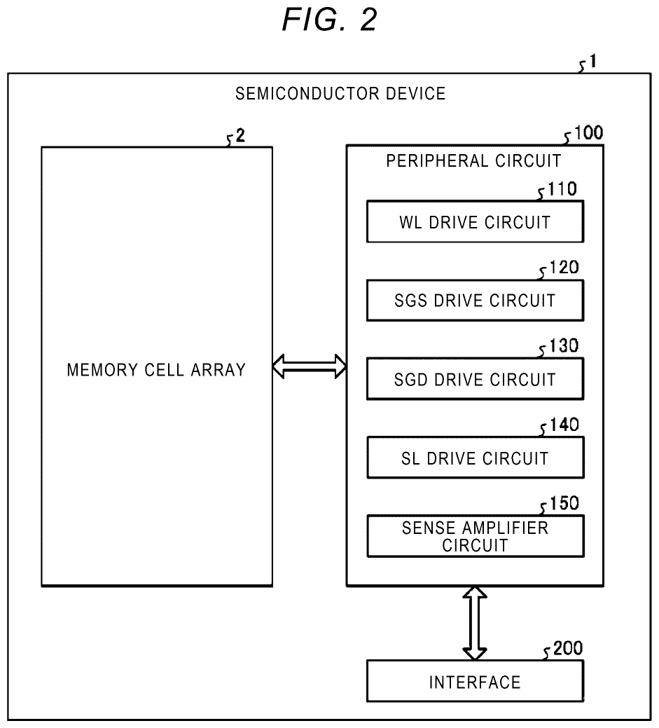

FIG. 2 is a block diagram illustrating a schematic configuration of the semiconductor device 1.

As illustrated in FIG. 2, the semiconductor device 1 includes the memory cell array 2, a peripheral circuit 100, and an interface 200. The peripheral circuit 100 includes a WL drive circuit 110, an SGS drive circuit 120, an SGD drive circuit 130, an SL drive circuit 140, and a sense amplifier circuit 150.

The WL drive circuit 110 is a circuit that controls an applied voltage to the word line WL, and the SGS drive circuit 120 is a circuit that controls a voltage applied to the select gate SGS. The SGD drive circuit 130 is a circuit that controls a voltage applied to the select gate SGD, and the SL drive circuit 140 is a circuit that controls a voltage applied to the source line SL. The sense amplifier circuit 150 is a circuit that controls a voltage applied to the bit line BL, and is also a circuit that determines read data depending on a signal from a selected memory cell.

The peripheral circuit 100 controls an operation of the semiconductor device 1 based on an instruction input from an external apparatus (for example, a memory controller of a memory system to which the semiconductor device 1 is applied) through the interface 200.

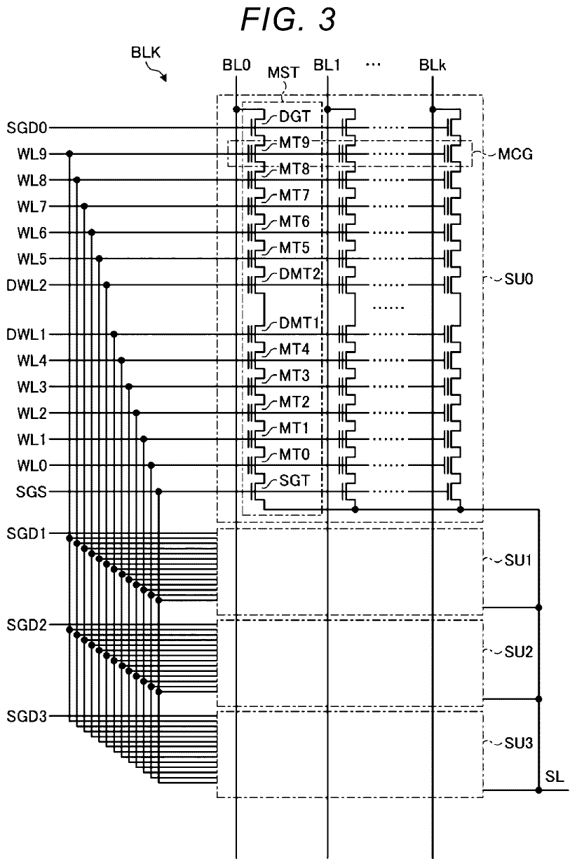

Next, the circuit configuration of the memory cell array 2 will be described using FIG. 3. FIG. 3 is a circuit diagram illustrating a configuration of the memory cell array 2.

The memory cell array 2 includes a plurality of blocks BLK each of which is a set including a plurality of memory cell transistors MT. Hereinafter, the memory cell transistor MT will be simply called a memory cell MT.

Each of the blocks BLK includes a plurality of string units SU0, SU1, SU2, and SU3 that are a set including memory cells MT associated with the word line WL and the bit line BL. Each of the string units SU0 to SU3 includes a plurality of memory strings MST where the memory cells MT are connected in series. The number of the memory strings MST in the string units SU0 to SU3 is any number.

The plurality of string units SU0, SU1, SU2, and SU3 correspond to a plurality of select gates SGD0, SGD1, SGD2, and SGD3, share the select gate SGS, and function as a plurality of drive units in the block BLK. Each of the string units SU can be driven by the select gate SGD and the select gate SGS corresponding thereto. In addition, each of the string units SU includes a plurality of memory strings MST.

Each of the memory strings MST includes, for example, ten memory cells MT (MT0 to MT9) and select transistors DGT and SGT. The memory cell MT includes a control gate and a charge storage film and latches and stores data in a nonvolatile manner. The ten memory cells MT are connected in series between a source of the select transistor DGT and a drain of the select transistor SGT. The number of the memory cells MT in the memory string MST is not limited to ten.

Gates of the select transistors DGT in the string units SU0 to SU3 are connected to the select gates SGD0 to SGD3. On the other hand, gates of the select transistors SGT in the string units SU are connected in common to, for example, the select gate SGS.

Drains of the select transistors DGT of the memory strings MST in the string units SU are connected to bit lines BL0 to BLk (k represents any integer of 2 or more) that are different from each other. In addition, the bit lines BL0 to BLk are connected in common to one memory string MST in each of the string units SU between the plurality of blocks BLK. Further, sources of the select transistors SGT are connected in common to the source line SL.

That is, the string unit SU is a set including the memory strings MST that are connected to the bit lines BL0 to BLk different from each other and are connected to the same select gate SGD. In addition, each of the blocks BLK is a set including the plurality of string units SU0 to SU3 that share the word line WL. The memory cell array 2 is a set including the plurality of blocks BLK that share the bit lines BL0 to BLk.

When a group including the memory cells MT that share the word line WL is referred to as “memory cell group MCG”, the memory cell group MCG is a minimum unit of a set including memory cells MT to which a predetermined voltage (for example, a write voltage or a read voltage) can be collectively applied via the word line WL.

In addition, a dummy word line DWL1 and a dummy word line DWL2 are provided between a word line WL4 and a word line WL5. A dummy memory cell DMT1 and a dummy memory cell DMT2 corresponding to the dummy word line DWL1 and the dummy word line DWL2 are provided between a memory cell MT4 and a memory cell MT5 in each of the memory strings MST. Each of the dummy memory cell DMT1 and the dummy memory cell DMT2 has the same structure as the memory cell MT and is not used for storing data.

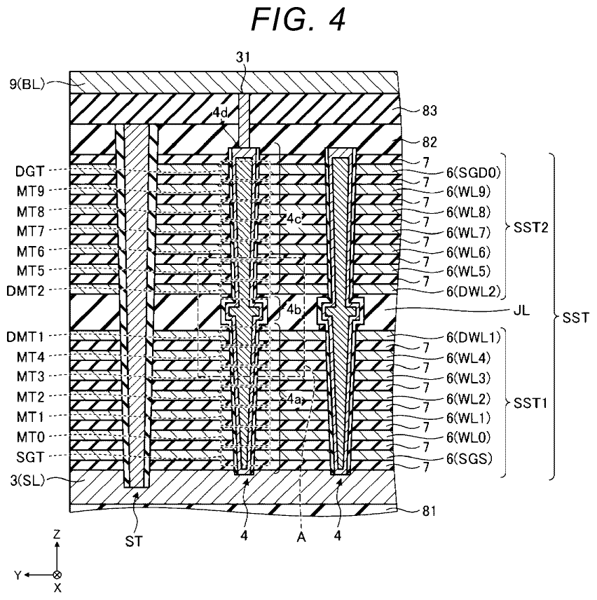

Next, a cross-sectional configuration of the memory cell array 2 will be described using FIG. 4. FIG. 4 is a cross-sectional view illustrating a configuration of the memory cell array 2.

In the semiconductor device 1, a conductive layer 3 is disposed on the +Z side of the substrate SUB through the interlayer insulating film 81. The conductive layer 3 can be formed of a material that includes a semiconductor (for example, silicon) including impurity as a major component or a material that includes a conductive material (for example, metal such as tungsten) as a major component. The conductive layer 3 extends in a plate shape in the X and Y directions and functions as the source line SL (refer to FIG. 1). The plurality of columnar bodies 4 are disposed on the +Z side of the conductive layer 3. The plurality of columnar bodies 4 are arranged in the X and Y directions. Each of the columnar bodies 4 extends in the Z direction and penetrates the stacked body SST (refer to FIG. 1).

The stacked body SST has a structure in which a plurality of stacked bodies SST1 and SST2 are stacked. FIG. 4 illustrates the structure where the stacked body SST is divided into the two stacked bodies SST1 and SST2. The stacked body SST may be divided into three or more stacked bodies.

In each of the columnar bodies 4 illustrated in FIG. 4, a tier 4a, a joint portion 4b, a tier 4c, and a cap layer 4d are stacked in this order on the +Z side of the conductive layer 3. In the stacked body SST, the stacked body SST1, a joint layer JL, and the stacked body SST2 are stacked in this order on the +Z side of the conductive layer 3. Each of the stacked bodies SST1 and SST2 has a configuration in which a conductive layer 6 that functions as the word line WL or the like is stacked through the insulating layer 7. The tier 4a extends in the Z direction and penetrates the stacked body SST1. The joint portion 4b has a Z position corresponding to the joint layer JL. The joint layer JL can be formed of a material that includes an oxide (for example, silicon oxide) as a major component. The tier 4c extends in the Z direction and penetrates the stacked body SST2. An end portion of the tier 4a on the +Z side is joined to the tier 4c through the joint portion 4b. The cap layer 4d extends in a plate shape in the X and Y directions and covers a +Z side end of the tier 4c. The cap layer 4d can be formed of, for example, a material that includes a semiconductor (for example, polysilicon) including impurity as a major component. On the +Z side of the stacked body SST2, a conductive layer 9 is disposed through interlayer insulating films 82 and 83. The conductive layer 9 can be formed of a material that includes a conductive material (for example, metal such as tungsten) as a major component. The conductive layer 9 extends linearly in the Y direction and functions as the bit line BL (refer to FIG. 1). The cap layer 4d is connected to the bit line BL through the contact plug 31.

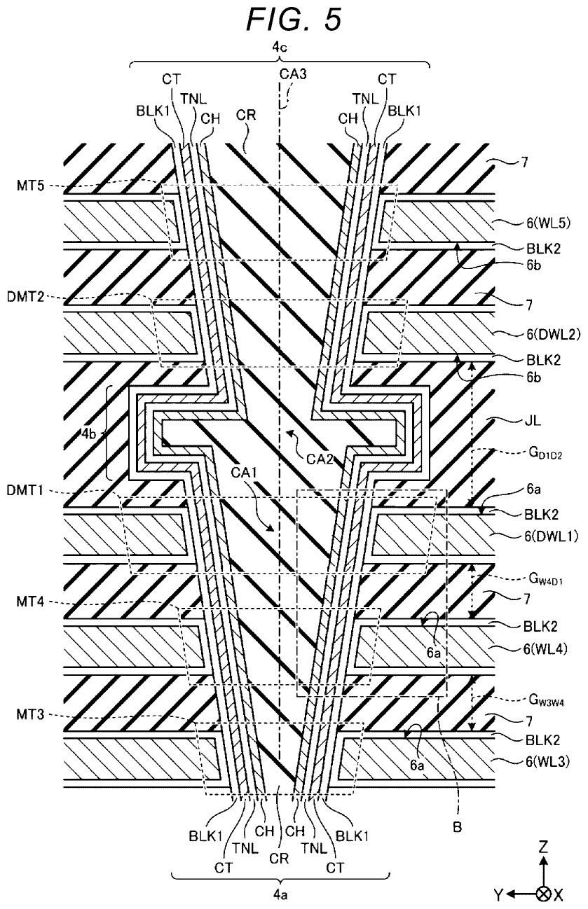

As illustrated in FIG. 5, the tiers 4a and 4c have a pillar shape having central axes CA1 and CA3 in the Z direction, for example, substantially a columnar shape. FIG. 5 is an enlarged cross-sectional view illustrating a configuration in the vicinity of the joint portion 4b, and is an enlarged cross-sectional view illustrating an enlarged A portion of FIG. 4. Each of the tiers 4a and 4c may have a tapered shape where a diameter of a −Z side end is smaller than a diameter of a +Z side end. Each of the tiers 4a and 4c may have a bowing shape where a diameter of a −Z side end is smaller than a diameter of a +Z side end and a diameter is wide at a predetermined Z position between the +Z side end and the −Z side end. The diameter of the −Z side end of the tier 4c is less than the diameter of the +Z side end of the tier 4a.

The joint portion 4b has a disk shape that has a central axis CA2 in the Z direction and extends in the X and Y directions. A −Z side surface of the joint portion 4b comes into contact with the +Z side end of the tier 4a, and a +Z side surface of the joint portion 4b comes into contact with the −Z side end of the tier 4c. The joint portion 4b joins the +Z side end of the tier 4a to the −Z side end of the tier 4c to join the tier 4a and the tier 4c to each other in the Z direction. The joint portion 4b has a larger diameter than the diameter of the +Z side end of the tier 4a, and has a larger diameter than the diameter of the −Z side end of the tier 4c. XY positions of the central axis CA2 of the joint portion 4b may be shifted from XY positions of the central axis CA1 of the tier 4a and/or XY positions of the central axis CA3 of the tier 4c. That is, the XY positions of the central axis CA1 of the tier 4a and the XY positions of the central axis CA3 of the tier 4c may be shifted from each other. As a result, margins for aligning the XY positions of the tier 4a and the tier 4c can be secured. The joint portion 4b has a larger width in the Z direction than a thickness of the conductive layer 6 in the Z direction, and has a larger width in the Z direction than a thickness of the insulating layer 7 in the Z direction. As a result, a margin for joining the tier 4a and the tier 4c can be secured. Accordingly, the joint layer JL has a larger thickness in the Z direction than the thickness of the conductive layer 6 in the Z direction, and has a larger thickness in the Z direction than the thickness of the insulating layer 7 in the Z direction.

As illustrated in FIG. 5, the tier 4a includes a core member CR, a semiconductor film CH, an insulating film TNL, a charge storage film CT, and an insulating film BLK1 in this order from the central axis CA1 side. The core member CR is disposed in the vicinity of the central axis CA1 of the tier 4a and has a substantially columnar shape extending along the central axis CA1 of the tier 4a. The core member CR can be formed of a material that includes an insulating material (for example, a semiconductor oxide such as silicon oxide) as a major component. The semiconductor film CH surrounds the core member CR from the outside, and has a substantially cylindrical shape extending along the central axis CA1 of the tier 4a. The semiconductor film CH covers an end portion of the core member CR on the −Z side and is connected to the conductive layer 3. The semiconductor film CH can be formed of a material that includes a semiconductor (for example, polysilicon) substantially not including impurity as a major component. The insulating film TNL surrounds the semiconductor film CH from the outside and has a substantially cylindrical shape extending along the central axis CA1 of the tier 4a. The insulating film TNL can be formed of a material that includes an oxide (for example, silicon oxide or silicon oxynitride) as a major component. The charge storage film CT surrounds the insulating film TNL from the outside and has a substantially cylindrical shape extending along the central axis CA1 of the tier 4a. The charge storage film CT can be formed of a material that includes a nitride (for example, silicon nitride) as a major component. The insulating film BLK1 surrounds the charge storage film CT from the outside and has a substantially cylindrical shape extending along the central axis CA1 of the tier 4a. The insulating film BLK1 can be formed of a material that includes an oxide (for example, silicon oxide, metal oxide, or a stacked body thereof) as a major component. As a result, an ONO type three-layer structure where the charge storage film CT is interposed between the pair of insulating films TNL and BLK1 can be configured.

The joint portion 4b includes the core member CR, the semiconductor film CH, the insulating film TNL, the charge storage film CT, and the insulating film BLK1 in this order from the central axis CA2 side. In the joint portion 4b, the core member CR has a substantially disk shape having a larger diameter than the core member CR of the tier 4a. The semiconductor film CH has a hollow disk shape having a larger diameter than the semiconductor film CH of the tier 4a. The insulating film TNL has a hollow disk shape having a larger diameter than the insulating film TNL of the tier 4a. The charge storage film CT has a hollow disk shape having a larger diameter than the charge storage film CT of the tier 4a. The insulating film BLK1 has a hollow disk shape having a larger diameter than the insulating film BLK1 of the tier 4a.

The tier 4c includes the core member CR, the semiconductor film CH, the insulating film TNL, the charge storage film CT, and the insulating film BLK1 in this order from the central axis CA3 side. The core member CR is disposed in the vicinity of the central axis CA3 of the tier 4c and has a substantially columnar shape extending along the central axis CA3 of the tier 4c. The semiconductor film CH surrounds the core member CR from the outside, and has a substantially cylindrical shape extending along the central axis CA3 of the tier 4c. The insulating film TNL surrounds the semiconductor film CH from the outside and has a substantially cylindrical shape extending along the central axis CA3 of the tier 4c. The charge storage film CT surrounds the insulating film TNL from the outside and has a substantially cylindrical shape extending along the central axis CA3 of the tier 4c. The insulating film BLK1 surrounds the charge storage film CT from the outside and has a substantially cylindrical shape extending along the central axis CA3 of the tier 4c. The core member CR, the semiconductor film CH, the insulating film TNL, the charge storage film CT, and the insulating film BLK1 of the tier 4c are formed of the same material as the core members CR, the semiconductor films CH, the insulating films TNL, the charge storage films CT, and the insulating films BLK1 of the tier 4a and the joint portion 4b. As a result, an ONO type three-layer structure where the charge storage film CT is interposed between the pair of insulating films TNL and BLK1 can be configured.

The semiconductor film CH of the tier 4a is connected to the conductive layer 3 as the source line SL on the −Z side, and is connected to the semiconductor film CH of the joint portion 4b on the +Z side. The semiconductor film CH of the joint portion 4b is connected to the semiconductor film CH of the tier 4c on the +Z side. An end portion of the semiconductor film CH of the tier 4c on the +Z side is connected to the conductive layer 9 functioning as the bit line BL through the cap layer 4d and the contact plug 31. That is, the semiconductor films CH of the tier 4a, the joint portion 4b, and the tier 4c include a channel region (active area) in the memory string MST.

In each of the stacked bodies SST1 and SST2 illustrated in FIG. 4, the conductive layer 6 and the insulating layer 7 are alternately and repeatedly stacked. Each of the conductive layers 6 extends in a plate shape in the X and Y directions. Each of the conductive layers 6 can be formed of a material that includes a conductive material (for example, metal such as tungsten) as a major component. In each of the conductive layers 6, a +Z side surface, a −Z side surface, and surfaces facing the tiers 4a and 4c may be covered with an insulating film BLK2. The insulating film BLK2 may have a different composition from the insulating film BLK1. The insulating film BLK2 can be formed of a material that includes an insulating material (for example, a metal oxide such as aluminum oxide, zirconium oxide, or hafnium oxide) as a major component. Each of the insulating layers 7 extends in a plate shape in the X and Y directions. Each of the insulating layers 7 can be formed of a material that includes an insulating material (for example, a semiconductor oxide such as silicon oxide) as a major component.

In the stacked body SST1, among the plurality of conductive layers 6 disposed distant from each other in the Z direction, at least the conductive layer 6 closest to the −Z side functions as the select gate SGS, at least the conductive layer 6 closest to the +Z side functions as the dummy word line DWL1, and the other conductive layers 6 function as the word lines WL0 to WL4. As illustrated in FIG. 1, the plurality of conductive layers 6 on the −Z side function as the select gates SGS. Likewise, the plurality of conductive layers 6 functioning as the dummy word lines DWL1 may be provided on the +Z side.

The select transistor SGT is formed at a position where the conductive layer 6 as the select gate SGS intersects with the semiconductor film CH and the charge storage film CT. The memory cell MT0 is formed at a position where the conductive layer 6 as the word line WL0 intersects with the semiconductor film CH and the charge storage film CT. The memory cell MT1 is formed at a position where the conductive layer 6 as the word line WL1 intersects with the semiconductor film CH and the charge storage film CT. The memory cell MT2 is formed at a position where the conductive layer 6 as the word line WL2 intersects with the semiconductor film CH and the charge storage film CT. The memory cell MT3 is formed at a position where the conductive layer 6 as the word line WL3 intersects with the semiconductor film CH and the charge storage film CT. The memory cell MT4 is formed at a position where the conductive layer 6 as the word line WL4 intersects with the semiconductor film CH and the charge storage film CT. The dummy memory cell DMT1 is formed at a position where the conductive layer 6 as the dummy word line DWL1 intersects with the semiconductor film CH and the charge storage film CT. At a position where the tier 4a intersects with the conductive layer 6 as the select gate SGS, the charge storage film CT and the insulating film BLK1 may be partially omitted.

In the stacked body SST2 stacked on the stacked body SST1 through the joint layer JL, among the plurality of conductive layers 6 disposed distant from each other in the Z direction, at least the conductive layer 6 closest to the +Z side functions as the select gate SGD, at least the conductive layer 6 closest to the −Z side functions as the dummy word line DWL2, and the other conductive layers 6 function as word lines WL5 to WL9. As illustrated in FIG. 1, the plurality of conductive layers 6 on the +Z side function as the select gates SGD. Likewise, the plurality of conductive layers 6 functioning as the dummy word lines DWL2 may be provided on the −Z side.

The dummy memory cell DMT2 is formed at a position where the conductive layer 6 as the dummy word line DWL2 intersects with the semiconductor film CH and the charge storage film CT. The memory cell MT5 is formed at a position where the conductive layer 6 as the word line WL5 intersects with the semiconductor film CH and the charge storage film CT. The memory cell MT6 is formed at a position where the conductive layer 6 as the word line WL6 intersects with the semiconductor film CH and the charge storage film CT. The memory cell MT7 is formed at a position where the conductive layer 6 as the word line WL7 intersects with the semiconductor film CH and the charge storage film CT. The memory cell MT8 is formed at a position where the conductive layer 6 as the word line WL8 intersects with the semiconductor film CH and the charge storage film CT. The memory cell MT9 is formed at a position where the conductive layer 6 as the word line WL9 intersects with the semiconductor film CH and the charge storage film CT. The select transistor DGT is formed at a position where the conductive layer 6 as the select gate SGD intersects with the semiconductor film CH and the charge storage film CT. At a position where the tier 4c intersects with the conductive layer 6 as the select gate SGD, the charge storage film CT and the insulating film BLK1 may be partially omitted.

In a write process of information into the memory cell MT, a write voltage is applied to the conductive layer 6 as the selected word line WL, a transfer voltage is applied to the conductive layer 6 as a non-selected word line WL, and a reference voltage is applied to the semiconductor film CH. The write voltage has a potential (for example, 20 V) for injecting charge (electrons) of the semiconductor film CH into the charge storage film CT. The transfer voltage has a potential (for example, 10 V) between the write voltage and the reference voltage. The reference voltage has a potential (for example, 0 V) as a reference. As a result, charge is stored in the charge storage film CT of the selected memory cell MT at a position where the conductive layer 6 as the selected word line WL intersects with the semiconductor film CH, and information is written into the selected memory cell MT.

In an erase process of information from the memory cell MT, the reference voltage is applied to the conductive layer 6 as each of the word lines WL, an erase voltage is applied to the semiconductor film CH, and an intermediate voltage is applied to the select gates SGS and SGD. The erase voltage has a potential (for example, 20 V) for injecting opposite charge (holes) of the semiconductor film CH into the charge storage film CT. The reference voltage has a potential (for example, 0 V) as a reference. The intermediate voltage has a potential (for example, 5 V) between the erase voltage and the reference voltage. Under this control, pairs of electrons and holes are generated by gate induced drain leakage (GIDL) in the vicinity of the drains of the select transistors SGT and DGT. The opposite charge (holes) is injected from the semiconductor film CH into the charge storage film CT. As a result, the charge stored in the charge storage film CT is erased, and information of the memory cell MT can be erased.

At this time, as illustrated in FIG. 5, in the conductive layer 6 as the dummy word line DWL1, due to the presence of the joint portion 4b, an interval G_{D1D2} in the Z direction from the conductive layer 6 on the +Z side is more than an interval G_{W4D1} in the Z direction from the conductive layer 6 on the −Z side. As a result, an electric field in a direction from the conductive layer 6 as the dummy word line DWL1 toward the charge storage film CT has a smaller effect of the voltage of the conductive layer 6 on the +Z side than the effect of the voltage of the conductive layer 6 on the −Z side. Therefore, electric field concentration may occur on a corner portion in a +Z side surface 6a of the conductive layer 6 as the dummy word line DWL1. As a result, charge tunneling the insulating film BLK1 from the corner portion in the +Z side surface 6a of the conductive layer 6 as the dummy word line DWL1 may be stored in the charge storage film CT in the vicinity of the joint portion 4b, that is, a back tunneling phenomenon may occur. The flow of the charge that tunnels the insulating film BLK1 from the conductive layer 6 and is stored in the charge storage film CT is also called a back tunneling current. When the back tunneling phenomenon occurs, unintended information is written into the charge storage film CT in the vicinity of the joint portion 4b, but the conductive layer 6 of the word line WL is not present in the vicinity of the joint portion 4b. Therefore, it is difficult to inject the opposite charge from the semiconductor film CH into the charge storage film CT to erase the charge.

On the other hand, in the conductive layer 6 as the word line WL4, the interval G_{W4D1} in the Z direction from the conductive layer 6 on the +Z side is equal to an interval G_{W3W4} in the Z direction from the conductive layer 6 on the −Z side. As a result, in the conductive layer 6 of the word line WL4, electric field concentration is likely to occur as in the conductive layer 6 as the dummy word line DWL1.

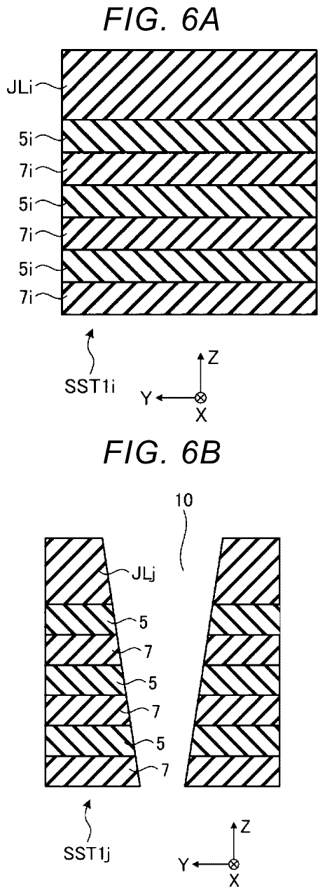

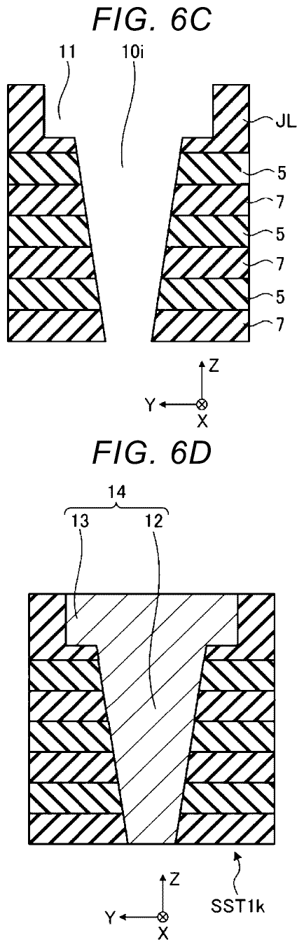

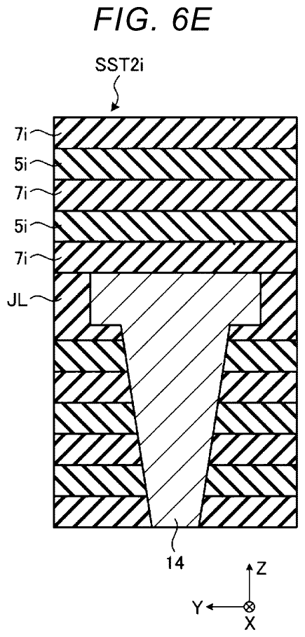

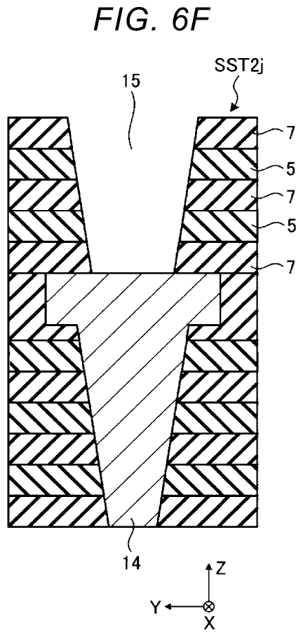

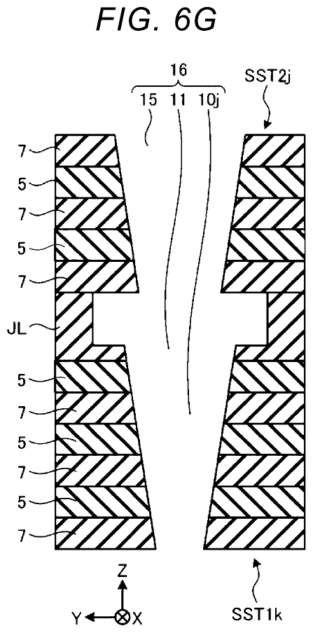

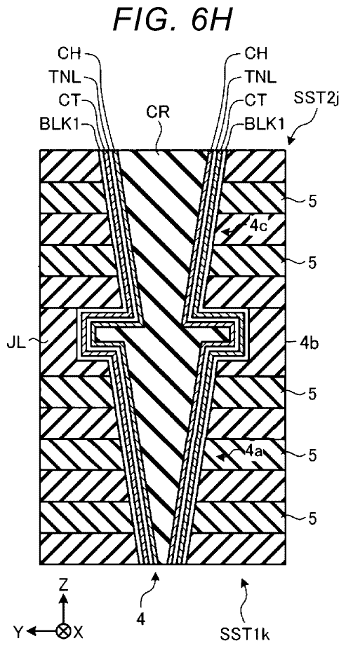

Next, a method of manufacturing the semiconductor device 1 will be described with reference to FIGS. 6A to 6I. FIGS. 6A to 6I are cross-sectional views illustrating the method of manufacturing the semiconductor device 1.

In a step illustrated in FIG. 6A, a transistor is formed on the substrate SUB (refer to FIG. 1), a contact plug, a wiring film, a via plug, and the like are formed on the substrate SUB, and the interlayer insulating film 81 is formed around these components. As a result, the peripheral circuit 100 is formed. The interlayer insulating film 81 can be formed on the +Z side of the substrate SUB by depositing a material that includes an insulating material (for example, a semiconductor oxide such as silicon oxide) as a major component (refer to FIG. 4). The conductive layer 3 is deposited on the +Z side of the interlayer insulating film 81. The conductive layer 3 can be formed of a material that includes a semiconductor (for example, silicon) including impurity as a major component or a material that includes a conductive material (for example, metal such as tungsten) as a major component.

A stacked body SST1i is formed on the +Z side of the conductive layer 3 by alternately depositing an insulating layer 7i and a sacrifice layer 5i multiple times. The insulating layer 7i can be formed of a material that includes an oxide (for example, silicon oxide) as a major component. The sacrifice layer 5i can be formed of a material that includes a nitride (for example, silicon nitride) as a major component. Each of the insulating layers 7i and each of the sacrifice layers 5i can be deposited with substantially the same film thickness.

A joint layer JLi is deposited on the +Z side of the stacked body SST1i. The joint layer JLi can be formed of a material that includes an oxide (for example, silicon oxide) as a major component. The joint layer JLi is formed with a film thickness more than the film thickness of the insulating layer 7i and the film thickness of the sacrifice layer 5i.

In a step illustrated in FIG. 6B, a resist pattern where a formation position of a memory hole 10 is opened is formed on the joint layer JLi. By executing anisotropic etching such as reactive ion etching (RIE) using the resist pattern as a mask, the memory hole 10 that penetrates a joint layer JLj and a stacked body SST1j and reaches the conductive layer 3 is formed.

In a step illustrated in FIG. 6C, a resist pattern where a formation position of a joint hole 11 is opened is formed on the joint layer JLj. The opening of the resist pattern is formed to include a memory hole 10i when seen from the Z direction. By executing anisotropic etching such as RIE using the resist pattern as a mask, the joint hole 11 is formed in the joint layer JL. The joint hole 11 is formed with a larger diameter than the memory hole 10i at a depth less than the thickness of the joint layer JL. The depth of the joint hole 11 can be adjusted based on an etching time of the anisotropic etching.

In a step illustrated in FIG. 6D, a sacrificial film 14 is embedded in the memory hole 10i and the joint hole 11. The sacrificial film 14 can be formed of a material (for example, a material including carbon) capable of ensuring etching selectivity for the insulating layer 7 and the sacrifice layer 5. The sacrificial film 14 includes a columnar portion 12 embedded in the memory hole 10i and a disk-shaped portion 13 embedded in the joint hole 11.

In a step illustrated in FIG. 6E, a stacked body SST2i is formed on the +Z side of the joint layer JL and the sacrificial film 14 by alternately depositing the insulating layer 7i and the sacrifice layer 5i multiple times. The insulating layer 7i can be formed of a material that includes an oxide (for example, silicon oxide) as a major component. The sacrifice layer 5i can be formed of a material that includes a nitride (for example, silicon nitride) as a major component. Each of the insulating layers 7i and each of the sacrifice layers 5i can be deposited with substantially the same film thicknesses as those of each of the insulating layers 7i and each of the sacrifice layers 5i (refer to FIG. 6A) in the stacked body SST1i.

In a step illustrated in FIG. 6F, a resist pattern where a formation position of a memory hole 15 is opened is formed on the stacked body SST2i. By executing anisotropic etching such as RIE using the resist pattern as a mask, the memory hole 15 that penetrates a stacked body SST2j and exposes a +Z side surface of the sacrificial film 14 is formed.

In a step illustrated in FIG. 6G, the sacrificial film 14 is removed. As a result, a memory hole 16 that penetrates the stacked body SST2j, the joint layer JL, and a stacked body SST1k and reaches the conductive layer 3 (refer to FIG. 4) is formed. The memory hole 16 includes the memory hole 10j, the joint hole 11, and the memory hole 15 in this order on the +Z side of the conductive layer 3.

In a step illustrated in FIG. 6H, the insulating film BLK1, the charge storage film CT, and the insulating film TNL are deposited in this order on a side surface and a bottom surface of the memory hole 16. The insulating film BLK1 can be formed of a material that includes an oxide (for example, silicon oxide, metal oxide, or a stacked body thereof) as a major component. The charge storage film CT can be formed of a material that includes a nitride (for example, silicon nitride) as a major component. The insulating film TNL can be formed of a material that includes an oxide (for example, silicon oxide or silicon oxynitride) as a major component. After selectively removing the portion of the bottom surface of the memory hole 16 in the insulating film BLK1, the charge storage film CT, and the insulating film TNL, the semiconductor film CH is deposited on the side surface and the bottom surface of the memory hole 16. The semiconductor film CH can be formed of a material that includes a semiconductor (for example, polysilicon) substantially not including impurity as a major component. The core member CR is embedded in the memory hole 16. The core member CR can be formed of a material that includes an insulating material (for example, a semiconductor oxide such as silicon oxide) as a major component. As a result, the columnar body 4 that penetrates the stacked body SST1k, the joint layer JL, and the stacked body SST2j in the Z direction is formed. The columnar body 4 includes the tier 4a that penetrates the stacked body SST1k in the Z direction, the joint portion 4b that substantially penetrates the joint layer JL in the Z direction, and the tier 4c that penetrates the stacked body SST2j in the Z direction in this order on the +Z side of the conductive layer 3.

In a step illustrated in FIG. 6I, a sacrifice layer 5 of the stacked body SST1k and the sacrifice layer 5 of the stacked body SST2j are removed. The insulating film BLK2 is deposited on an exposed surface of a gap that is formed by the removal. The insulating film BLK2 can be formed of a material that includes an insulating material (for example, a metal oxide such as aluminum oxide, zirconium oxide, or hafnium oxide) as a major component. The conductive layer 6 is embedded in the gap. The conductive layer 6 can be formed of a material that includes a conductive material (for example, metal such as tungsten) as a major component. As a result, the stacked body SST1 where the conductive layer 6 and the insulating layer 7 are alternately and repeatedly stacked is formed, and the stacked body SST2 where the conductive layer 6 and the insulating layer 7 are alternately and repeatedly stacked is formed.

Next, a configuration of a mark 310 will be described.

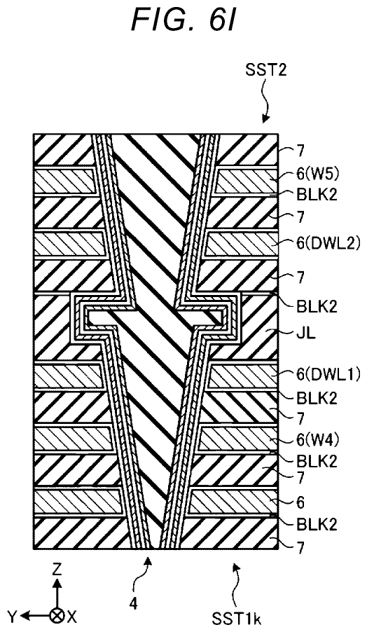

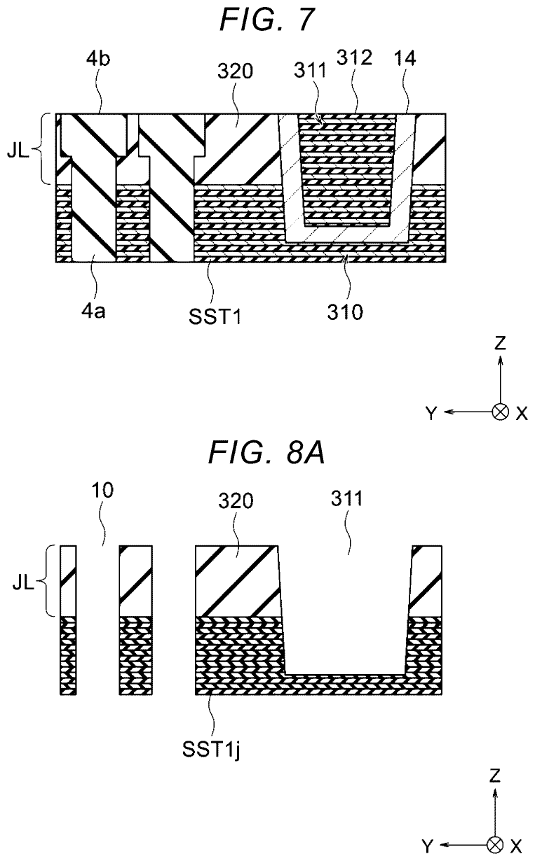

FIG. 7 is a cross-sectional view illustrating a configuration of the mark 310 according to the first embodiment. FIG. 7 illustrates a peripheral configuration of the tier 4a, the joint portion 4b, and the mark 310. In FIG. 7, the film such as the charge storage film CT is not illustrated.

The mark 310 is an alignment mark. The mark 310 is provided on an upper surface of an interlayer insulating film 320. The interlayer insulating film 320 is provided on the substrate SUB. The mark 310 is disposed at a position different from the stacked body SST in the X and Y directions. The mark 310 is disposed in a curve portion between adjacent chips where the semiconductor device 1 is provided. The mark 310 is disposed, for example, between a dicing line on a wafer and the memory cell array 2.

The mark 310 has, for example, a wider line shape when seen from the Z direction. When seen from the Z direction, a length of the mark 310 is, for example, 5 μm, and a width of the mark 310 is, for example, 1 μm. The width of the mark 310 is, for example, about ten times the width of the memory hole 10. A plurality of marks may be disposed adjacent to each other when seen from the Z direction.

The mark 310 includes a recess portion 311, the sacrificial film 14, and an upper layer member 312.

The recess portion 311 extends, for example, in the −Z direction from an upper surface of the joint portion 4b. In the example illustrated in FIG. 7, the recess portion 311 extends up to the inside of the stacked body SST1, and the stacked body SST1 is positioned below the mark 310. In addition, the position of the joint portion 4b from the substrate SUB (position of the joint portion 4b in the Z direction) is the same as the position of the mark 310 from the substrate SUB (the position of the mark 310 in the Z direction). As described below, the recess portion 311 is formed simultaneously with the memory hole 10 of the tier 4a.

The sacrificial film 14 is provided on the inner surface and the bottom surface of the recess portion 311. The sacrificial film 14 has hydrophobicity. As described below, the upper surface of the sacrificial film 14 has hydrophilicity.

The sacrificial film 14 contains, for example, carbon such as diamond-like carbon or amorphous carbon. In addition, the sacrificial film 14 is not limited to containing carbon and may contain polycrystalline silicon, amorphous silicon, silicon carbide, or silicon nitride.

The upper layer member 312 is provided on the joint layer JL, and a part thereof is provided to be embedded in the recess portion 311. FIG. 7 illustrates the upper layer member 312 a part of which is embedded in the recess portion 311. In the example illustrated in FIG. 7, the upper layer member 312 a part of which is embedded in the recess portion 311 is a part of the stacked body SST2. In the vicinity of the mark 310, a part of the sacrifice layer 5 of the stacked body SST2j may remain without being replaced with the conductive layer 6 of the stacked body SST2. In the upper layer member 312 above the recess portion 311, there is a level difference due to the recess portion 311.

Next, regarding the formation of the mark 310, the details of the steps illustrated in FIGS. 6B to 6D will be described.

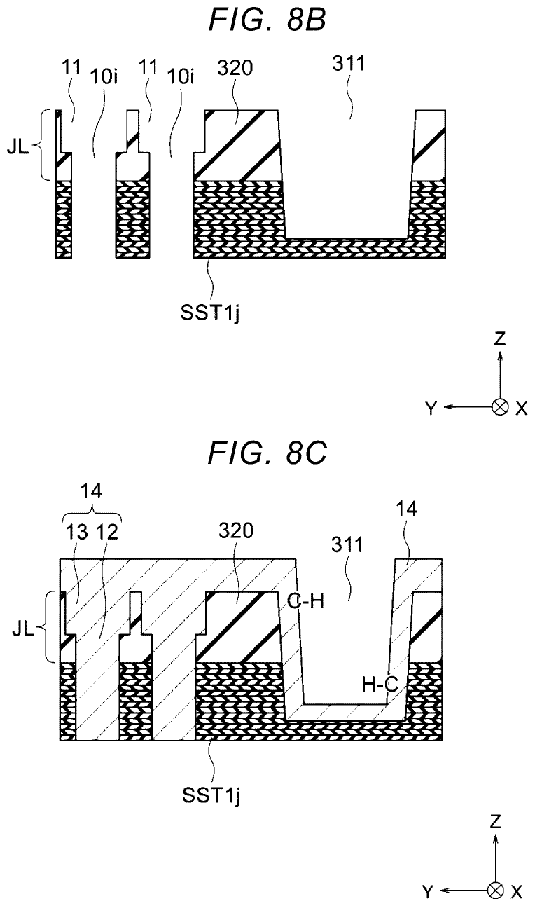

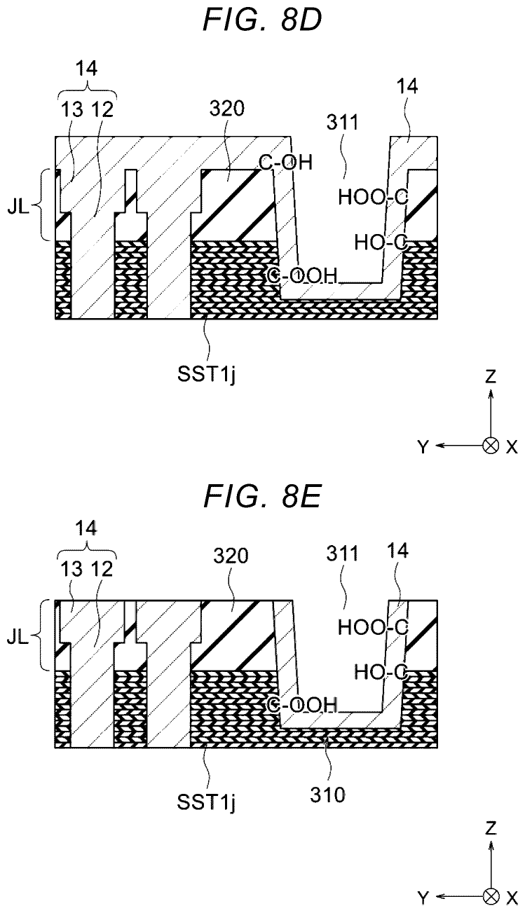

FIGS. 8A to 8E are cross-sectional views illustrating the method of manufacturing the semiconductor device 1 according to the first embodiment. FIG. 8A corresponds to the step illustrated in FIG. 6B. FIG. 8B corresponds to the step illustrated in FIG. 6C. FIGS. 8C to 8E corresponds to the step illustrated in FIG. 6D.

After forming the stacked body SST1i and the interlayer insulating film 320 around the stacked body SST1i (refer to FIG. 6A), the memory hole 10 and the recess portion 311 are formed as illustrated in FIG. 8A. That is, the memory hole 10 and the recess portion 311 are formed simultaneously (in parallel). The recess portion 311 is formed at the position of the mark 310.

Next, as illustrated in FIG. 8B, the joint hole 11 is formed in the joint layer JL.

Next, as illustrated in FIG. 8C, the sacrificial film 14 is embedded in the memory hole 10i and the joint hole 11, and the sacrificial film 14 is formed on the upper surface of the interlayer insulating film 320 and the inner surface and the bottom surface of the recess portion 311. Many —CH groups and —CH₃ groups are present on the surface of the sacrificial film 14. Since the —CH groups and the —CH₃ groups have hydrophobicity, the sacrificial film 14 has hydrophobicity.

Next, as illustrated in FIG. 8D, the upper surface of the sacrificial film 14 is treated to be hydrophilic. It is preferable that the treatment of the sacrificial film 14 to be hydrophilic is executed in a device for polishing the sacrificial film 14 in the subsequent step. The hydrophilic treatment is executed, for example, by chemical oxidation, plasma exposure (oxygen plasma), ion beam irradiation, or a heat treatment in an oxide atmosphere.

The chemical oxidation is, for example, a wet treatment using O₃, H₂O₂, or HNO₃.

In the plasma exposure, oxygen gas is caused to flow through an electrode to apply a high frequency and a high voltage. The oxygen gas is converted into a plasma to generate an oxygen radical. The surface of the sacrificial film 14 that is a hydrophobic material is irradiated with the oxygen radical. When the sacrificial film 14 is silicon carbide, amorphous carbon, diamond-like carbon, or the like, a C—H bond and a C—CH₃ bond that are hydrophobic groups on the surface is cut to form a hydrophilic group such as —C—OH or —C═O. These hydrophilic group have high polarity, and the hydrophilicity of the surface of the sacrificial film 14 is improved. When the sacrificial film 14 is silicon nitride, amorphous silicon, or polycrystalline silicon, a Si—O bond is formed on the surface to improve the hydrophilicity.

In the ion beam irradiation, electrons are caused to collide with the oxygen gas to generate oxygen ions. The oxygen ions are emitted, for example, when the sacrificial film 14 is amorphous silicon or polycrystalline silicon. The oxygen ions enter into silicon (Si) solid, and silicon oxide (SiO₂) is formed only on the surface of the sacrificial film 14 such that the sacrificial film 14 is treated to be hydrophilic.

In the example illustrated in FIG. 8D, a —COH group and a —COOH group are present on the surface of the sacrificial film 14 due to the hydrophilic treatment. Since the —COH group and the —COOH group have hydrophilicity, the upper surface of the sacrificial film 14 (the inner surface of the recess portion 311) has hydrophilicity.

Next, as illustrated in FIG. 8E, the sacrificial film 14 is polished such that the upper surface of the joint layer JL (interlayer insulating film 320) is exposed. The sacrificial film 14 is polished, for example, by chemical mechanical polishing (CMP).

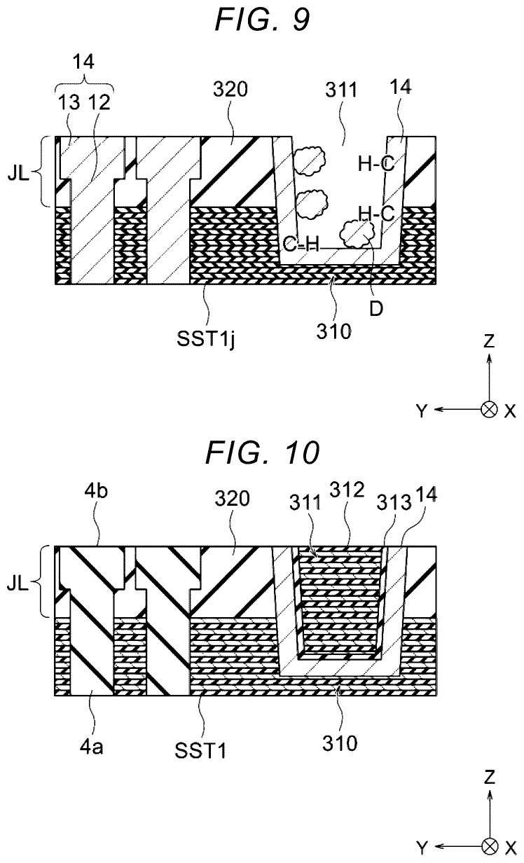

The upper surface of the sacrificial film 14 (the inner surface of the recess portion 311) has hydrophilicity, and a contact angle between the sacrificial film 14 and water is, for example, less than 15°. In general, hydrophobic dust is likely to be attached to the hydrophobic surface and is not likely to be attached to the hydrophilic surface. Accordingly, the hydrophobic dust is not likely to be attached to the surface of the recess portion 311 including hydrophilic sacrificial film 14. In addition, liquid (for example, including water as a major component) during the polishing by the CMP efficiently flows into the recess portion 311, and even when a residue of the polished sacrificial film 14 is attached to the sacrificial film 14, the residue is likely to be removed. As a result, the residue of the polished sacrificial film 14 is not likely to be fixed in the recess portion 311 as a dust D (refer to FIG. 9).

Next, steps illustrated in and after FIG. 6E are executed. As illustrated in FIG. 7, the sacrificial film 14 remains in the recess portion 311.

As described above, according to the first embodiment, the sacrificial film 14 having hydrophobicity is formed on the upper surface of the interlayer insulating film 320 and at least the inner surface of the recess portion 311. In addition, the upper surface of the sacrificial film 14 is treated to be hydrophilic. In addition, the sacrificial film 14 is polished until the upper surface of the interlayer insulating film 320 is exposed. As a result, the occurrence of clogging caused when the dust D is fixed in the recess portion 311 can be prevented. As a result, a decrease in overlapping accuracy can be reduced.

### Comparative Example

FIG. 9 is a cross-sectional view illustrating a method of manufacturing the semiconductor device 1 according to Comparative Example. Comparative example is different from the first embodiment in that the hydrophilic treatment is not executed. FIG. 9 corresponds to the drawing.

After forming the sacrificial film 14 (refer to FIG. 8C), as illustrated in FIG. 9, the sacrificial film 14 is polished until the joint layer JL is exposed. The sacrificial film 14 is polished, for example, by CMP.

The sacrificial film 14 itself that is the residue after the polishing has hydrophobicity. In addition, the surface of the sacrificial film 14 in the recess portion 311 also has hydrophobicity. Since the hydrophobic films in water are likely to adhere to each other, the residue is likely to be attached to the sacrificial film 14 in the recess portion 311, and water is not likely to flow on the surface of the recess portion 311. Accordingly, the dust D is likely to be fixed in the recess portion 311. The fixed dust D is not likely to be removed by cleaning after the polishing. In the mark 310 where the dust D is clogged, the visibility deteriorates. For example, when the dust D is fixed in the inner surface (side wall) of the recess portion 311, the level difference in the inner surface of the recess portion 311 decreases, and the level difference becomes inconspicuous. As a result, the overlapping accuracy decreases.

On the other hand, in the first embodiment, the sacrificial film 14 that is hydrophobic before polishing the sacrificial film 14 is treated to be hydrophilic. As a result, the occurrence of clogging caused when the dust D is fixed in the recess portion 311 can be prevented. As a result, a decrease in overlapping accuracy can be reduced.

### Second Embodiment

FIG. 10 is a cross-sectional view illustrating a configuration of the mark 310 according to a second embodiment. The second embodiment is different from the first embodiment, in that a film 313 having hydrophobicity is provided instead of treating the sacrificial film 14 to be hydrophobic.

The mark 310 further includes the film 313. The film 313 is provided on the sacrificial film 14. The film 313 has hydrophobicity. As a result, the recess portion 311 has hydrophilicity on the inner surface. The film 313 includes, for example, SiO₂.

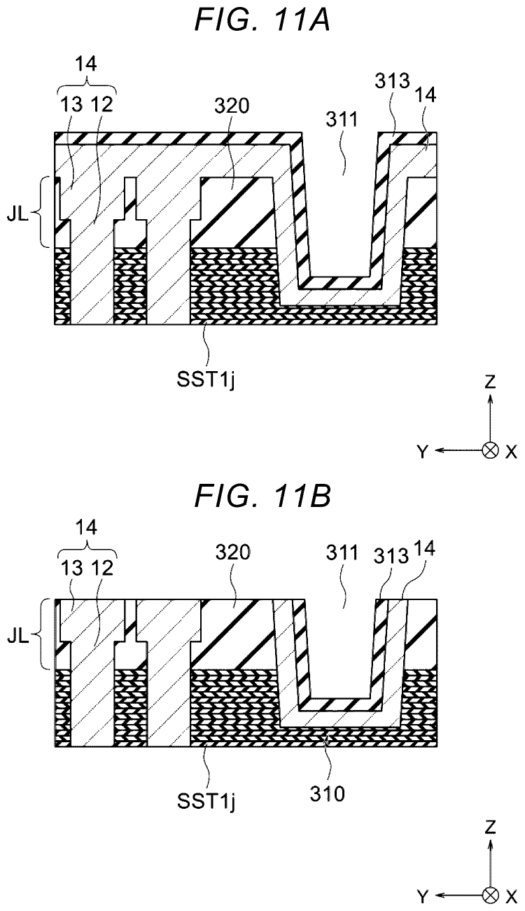

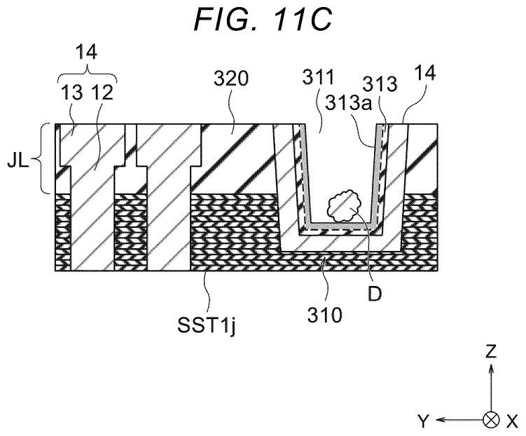

FIGS. 11A to 11C are cross-sectional views illustrating a method of manufacturing the semiconductor device 1 according to the second embodiment.

After forming the sacrificial film 14 (refer to FIG. 8C), the film 313 is formed on the sacrificial film 14 as illustrated in FIG. 11A. The film 313 can be formed of, for example, a material that includes an oxide (for example, silicon oxide) as a major component. The film 313 is formed, for example, by chemical vapor deposition (CVD).

Next, as illustrated in FIG. 11B, the sacrificial film 14 and the film 313 are polished such that the joint layer JL (interlayer insulating film 320) is exposed. The sacrificial film 14 and the film 313 are polished, for example, by CMP. The film 313 having hydrophilicity is formed on the inner surface and the bottom surface of the recess portion 311. Therefore, the residue of the polished sacrificial film 14 is not likely to be fixed in the recess portion 311 as the dust D. Since the film 313 has hydrophilicity, the residue of the film 313 is not likely to be the large dust D.

Next, as illustrated in FIG. 11C, a surface portion 313a that is a part of the upper surface of the film 313 is removed. The removal of the surface portion 313a is executed, for example, by cleaning the inside of the device after CMP. When the film 313 includes silicon oxide, the removal of the surface portion 313a is executed, for example, using dilute hydrogen fluoride (DHF). When the dust D is fixed in the recess portion 311, not only the surface portion 313a but also the dust D are removed. As a result, the dust D can be prevented from being fixed in the recess portion 311. The step illustrated in FIG. 11C may be skipped.

As in the second embodiment, the film 313 having hydrophobicity may be provided. In the semiconductor device 1 according to the second embodiment, the same effects as those of the first embodiment can be obtained.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method for manufacturing a semiconductor device, the method comprising:
forming an insulating film on a substrate;
forming a recess portion extending toward the substrate from an upper surface of the insulating film;
forming a first film on the upper surface of the insulating film and along an inner surface of the recess portion, wherein the first film has hydrophobicity;
treating an upper surface of the first film to be hydrophilic; and
polishing the first film until the upper surface of the insulating film is exposed.

2. The method of manufacturing a semiconductor device according to claim 1,
wherein treating the upper surface of the first film includes a chemical oxidation treatment, plasma exposure, ion beam irradiation, or a heat treatment in an oxide atmosphere.

3. The method of manufacturing a semiconductor device according to claim 1,
wherein treating the upper surface of the first film includes forming a second film having hydrophilicity on the first film.

4. The method of manufacturing a semiconductor device according to claim 3,
wherein the second film includes SiO₂.

5. The method of manufacturing a semiconductor device according to claim 3, further comprising removing a part of an upper surface of the second film after polishing the first film.

6. The method of manufacturing a semiconductor device according to claim 1, further comprising:
prior to forming the insulating film, forming a stacked body including insulating layers and sacrifice layers alternately stacked on top of one another,
wherein forming the recess portion includes forming a plurality of holes that penetrate through the stacked body, the plurality of holes further extending from the recess portion, respectively, and
forming the first film further includes embedding the first film in the plurality of holes.

7. The method of manufacturing a semiconductor device according to claim 1,
wherein the first film includes diamond-like carbon, amorphous carbon, polycrystalline silicon, amorphous silicon, silicon carbide, or silicon nitride.

8. A semiconductor device comprising:
a substrate;
an insulating film provided on the substrate; and
an alignment mark provided on an upper surface of the insulating film,
wherein the alignment mark includes:
a recess portion extending toward the substrate from the upper surface of the insulating film, and
a first film having hydrophobicity and provided along an inner surface of the recess portion.

9. The semiconductor device according to claim 8,
wherein an upper surface of the first film has hydrophilicity.

10. The semiconductor device according to claim 8,
wherein the alignment mark further includes a second film having hydrophilicity and provided on the first film.

11. The semiconductor device according to claim 10, wherein the second film includes SiO₂.

12. The semiconductor device according to claim 8, further comprising:
a stacked body provided on the substrate and including insulating layers and conductive layers alternately stacked on top of one another; and
a plurality of columnar bodies penetrating through the stacked body.

13. The semiconductor device according to claim 12,
wherein the columnar body includes:
a first columnar portion,
a second columnar portion, and
a joint portion provided between the first columnar portion and the second columnar portion,
wherein a position of the joint portion from the substrate is aligned with a position of the mark from the substrate.

14. The semiconductor device according to claim 8,
wherein the first film includes diamond-like carbon, amorphous carbon, polycrystalline silicon, amorphous silicon, silicon carbide, or silicon nitride.
